(19) United States
(12) Patent Application Publication
(10) Pub. No.: US 2026/0221199 A1
(43) Pub. Date: Jul. 30, 2026

(54) NONVOLATILE MEMORY WITH SENSING ARCHITECTURE INCLUDING SUPPLY-DEPENDENT RESISTANCE

(71) Applicant: TEXAS INSTRUMENTS INCORPORATED, Dallas, TX (US)

(72) Inventors: Tejas Ketkar, Noida (IN); Rohan Sinha, BENGALURU (IN); Rajat Kulshrestha, BENGALURU (IN)

(21) Appl. No.: 19/040,929

(22) Filed: Jan. 30, 2025

(51) Int. Cl. G11C 16/26; G11C 16/24

(52) U.S. Cl. CPC G11C 16/26; G11C 16/24

(57) ABSTRACT

A semiconductor device comprises an NVM array including a plurality of bitcells arranged in rows and columns, each column of bitcells associated with a corresponding bitline, where a bitcell includes a select transistor and a storage transistor. The semiconductor device includes a plurality of sensing interface circuits, each sensing interface circuit disposed between a respective bitline and a corresponding sense amplifier, where a sensing interface circuit includes a sense path transistor having a node (Vdn) configurable to have a voltage modulated by a voltage-dependent resistance.

### FIELD OF THE DISCLOSURE

Disclosed implementations relate generally to the field of semiconductor memory and fabrication. More particularly, but not exclusively, the disclosed implementations relate to nonvolatile memory.

### BACKGROUND

Nonvolatile memory (NVM) is a storage medium that may store information in an array of memory cells, also referred to as bitcells, which retain the information even after power is removed. This stored information (or “bits”) can be erased, programmed, and read. In some cases, an array of bitcells may be used in creating an NVM circuit, often referred to as a macro, which may be deployed in a variety of applications, e.g., standalone memory applications, System on a Chip (SoC) applications, embedded memory applications, etc.

Nonvolatile memory devices are commonplace in modern electronic systems, particularly in portable electronic devices and systems. Conventional types of NVM devices include electrically programmable read-only memory (EPROM) devices where memory cells may comprise one or more “floating-gate” (FG) transistors that store a data state. In a general sense, floating-gate transistors are “programmed” by the application of a bias that enables charge carriers, e.g., holes or electrons, to tunnel or be injected through a thin dielectric film onto an electrically isolated transistor gate element, which is operable as the floating gate of the transistor. The trapped charge in/on the floating gate is operable to modulate the apparent threshold voltage of the memory cell transistor, which may be referred to as a storage transistor or storage element, as compared with the threshold voltage with no charge trapped in the floating gate. This difference in threshold voltage can be detected by sensing the resulting difference in source-drain conduction of the storage element between the programmed and unprogrammed states under applicable transistor bias conditions.

Some EPROM devices are “erasable” in that the trapped charge can be removed from the floating gate. For example, the trapped charge may be removed by exposure of the memory cells to ultraviolet (UV) light. Such memories referred to as “UV EPROMS”. In other memory architectures referred to as electrically-erasable or electrically-alterable memories, i.e., EEPROMs and EAPROMS, respectively, a particular electrical bias condition may be applied that enables tunneling of the charge from the floating gate. “Flash” memory devices are typically realized as EEPROM memory arrays in which the erase operation may be applied simultaneously to a block of memory cells.

“One-time programmable” (OTP) and “multiple-time programable” (MTP) memories are also popular, especially in embedded NVM applications. Whereas the memory cells of OTP and MTP memories are constructed using FG-based storage cells similar to the EPROM devices, the OTP cells are not erasable and may be programmed only once.

Regardless of the type of NVM architecture implemented, it is desirable that an NVM device is operable over a broad range of supply voltages such that the NVM device may be deployed in a variety of application environments. In particular, where products are realized based on NVM arrays that are provided as intellectual property (IP) cores, it is important that IP cores are compatible with different voltage conditions and power budgets. However, designing NVM devices that are versatile across a broad range of supply voltages without compromising key performance indicators is challenging.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device comprising an NVM array is disclosed. The NVM array includes a plurality of bitcells arranged in rows and columns, each column of bitcells associated with a corresponding bitline, where a bitcell includes a select transistor and a storage transistor. The semiconductor device includes a plurality of sensing interface circuits, each sensing interface circuit disposed between a respective bitline and a corresponding sense amplifier, where a sensing interface circuit includes a sense path transistor having a node configurable to have a voltage modulated by a voltage-dependent resistance. In an example implementation, the voltage-dependent resistance may comprise an n-channel MOS (NMOS) transistor having a gate driven by a voltage divider coupled to a supply voltage.

In one example, a method of fabricating a semiconductor device including a nonvolatile memory is disclosed. The method may comprise forming a nonvolatile memory array in or over a semiconductor substrate, the nonvolatile memory array including a plurality of bitcells arranged in rows and columns, where each column of bitcells is associated with a corresponding bitline. Each bitcell may include a select transistor and a storage transistor coupled in series. The method may comprise forming a plurality of sensing interface circuits in or over the semiconductor substrate, each sensing interface circuit disposed between a respective bitline and a corresponding sense amplifier, where a sensing interface circuit includes a sense path transistor having a node configurable to have a voltage modulated by a voltage-dependent resistance.

### BRIEF DESCRIPTION OF DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIG. 1 depicts a block diagram of a nonvolatile memory (NVM) device including a sensing architecture with supply voltage dependent resistance for modulating a node along a data sense path according to some examples of the present disclosure;

FIG. 2 depicts a block diagram of an NVM device including a baseline sensing architecture;

FIGS. 3A and 3B depict block diagrams of an NVM device including sensing architectures according to some examples of the present disclosure;

FIG. 4A depicts waveforms associated with a baseline sensing architecture illustrating a false read scenario;

FIG. 4B depicts waveforms associated with an example sensing architecture of the present disclosure illustrating absence of a false read scenario;

FIG. 5 depicts waveforms associated with a baseline sensing architecture and a sensing architecture of the present disclosure illustrating reduced read access time according to some examples;

FIGS. 6A and 6B depict waveforms associated with a baseline sensing architecture and a sensing architecture of the present disclosure, respectively, illustrating reduced voltage stress across a storage cell according to some examples; and

FIG. 7 is a flowchart of an example method of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of FG-based NVM architectures where a plurality of memory cells are organized in an array having rows and columns and each memory cell includes an FG storage transistor coupled to a wordline select transistor.

In NVM architectures, a sensing interface circuit coupled to a respective bitline is utilized to sense the programmed current of a memory cell, also referred to as a bitcell, allowing the programmed data of the bitcell to be read. In order to ensure long-term reliability of the NVM device, source-drain voltage across the storage transistors is designed to be below a limit regardless of the supply voltage environment. However, transistors used in the sensing interface circuit may experience a range of process, voltage and temperature (PVT) variations, referred to herein as process corners, which can cause several undesirable effects with respect to reliability. For example, a sense path transistor associated with a selected bitline may encounter strong process corners, which may result in a source-drain voltage (Vsd or Vds) across the selected storage transistor (e.g., comprising the FG element) that exceeds a design specification. After several read/write cycles, such excursions of Vds voltage may cause soft programming of the bitcells, which may sometimes be referred to as read disturb. Depending on implementation, the risk of soft programming of bitcells may become particularly significant at higher supply voltages, e.g., VDD at around 5.0 V.

To prevent soft programming of the bitcells in NVM, sense path transistors of a sensing interface circuit may be resized in some example implementations, which may prevent Vds excursions of the storage transistors. However, resizing the sense path transistors may increase the risk of false zero reads, i.e., a bitcell programmed with a binary data of 1 being erroneously read as a 0 (e.g., as an erased bit). The issue of falsely reading a programmed bitcell as an erased bitcell may become more pronounced in NVM architectures operating with lower VDD supply voltages, e.g., voltages of about 1.0 V to about 2.0 V, especially in weak process corners. In addition, the risk of false reading of programmed bitcells may increase in end-of-life (EOL) scenarios where bitcell currents are generally lower. Designing an NVM operable with a range of supply voltages (e.g., VDD ranging from about 1.0 V to 5.0 V) while balancing the objectives of preventing soft programming at higher supply voltages and mitigating the risk of misreading programmed data at lower supply voltages is therefore demanding.

Examples of the present disclosure recognize the foregoing challenges and provide a supply voltage dependent biasing scheme in association with NVM sensing architecture to mitigate the risk of false 0 reads while simultaneously maintaining immunity to soft programming of the bitcells over a range of supply voltages. Further, disclosed examples of NVM sensing architecture are tolerant of varying process conditions, e.g., including both strong process corners as well as weak process corners. For purposes herein, “strong process corners” may refer to PVT conditions that may cause lower threshold voltages of the transistors in a sensing interface circuit. Conversely, “weak process corners” may refer to PVT conditions that may cause higher threshold voltages of the transistors.

In examples herein, a sensing interface feedback mechanism is provided in association with each data sense path where a feedback MOSFET may be configured to operate as a supply-dependent resistance controlled by a voltage divider that is coupled to a supply voltage rail. The feedback MOSFET may be configured to control a sense path transistor of the data sense path corresponding to a selected bitline, where the sense path transistor may be sized appropriately to reduce the risk of soft programming at higher supply voltages. In some examples, the sense path transistor may be sized such that the Vds of the storage cell remains less than a particular level for a given fabrication flow and its strong process corners.

For higher supply voltages, the feedback MOSFET device may be configured to operate such that the gate and the drain of the sense path transistor are effectively shorted. In this mode, the sense path transistor continues to operate so as not to cause the Vds of the storage transistor to exceed a designed voltage level. In this manner, the risk of soft programming of bitcells is mitigated in higher voltage environments and/or in strong process corners.

At lower supply voltages, the feedback MOSFET device is operable to cause a voltage difference between the gate and the drain of the sense path transistor, such that the drain voltage is modulated to be less than the gate voltage. Because the sense path transistor is coupled to column multiplex transistors along the data sense path of a selected bitline, reduced drain voltage of the sense path transistor operates to increase Vgs of the column multiplex transistors, which in turn improves current conduction in the column multiplex transistors. Accordingly, weak read currents associated with programmed bitcells in EOL conditions may be propagated more effectively to the sense interfacing circuits for facilitating improved logic level discrimination, thus reducing the risk of false 0 reads in lower voltage environments and/or in weak process corners.

Furthermore, because the Vgs of column multiplex transistors is improved, multi-transistor transmission gate arrangements including both p-channel MOS (PMOS) and n-channel (NMOS) devices used in some baseline column multiplex arrangements may be replaced by column multiplex circuitry comprising only NMOS transistors according to the examples herein. As the transistor count along a data sense path is reduced, signal propagation delay may also be reduced in some example arrangements of the present disclosure. Accordingly, read access times associated with an NVM may be advantageously reduced in the examples herein. Moreover, elimination of PMOS devices from column multiplex circuitry may help reduce the circuit area of an NVM and hence the die area in some example arrangements. Whereas the examples of the present disclosure may provide various circuit arrangements as well as associated structures, materials and processes that may engender these and other beneficial effects, no particular result is a requirement unless explicitly recited in a particular claim.

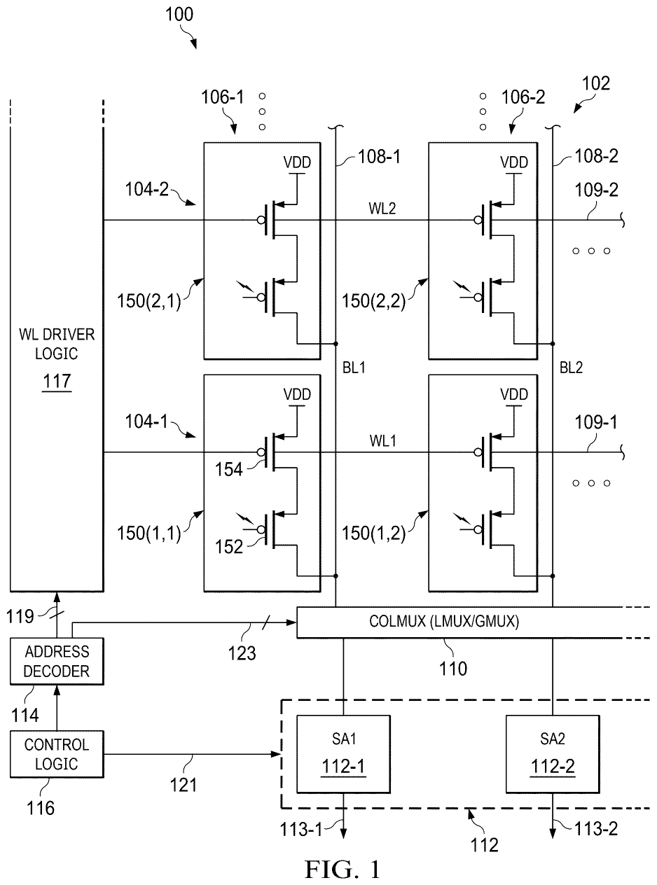

Referring to the drawings, FIG. 1 depicts a block diagram of a nonvolatile memory (NVM) device 100 including a sensing architecture where a supply voltage dependent resistance may be provided according to some examples of the present disclosure. A plurality of bitcells, e.g., bitcells 150(1,1) to 150(i,j), where i and j are positive integers M and N, respectively, may be organized as an array 102, also referred to as a bitcell array, having a plurality of rows 104-1 to 104-M and a plurality of columns 106-1 to 106-N. By way of illustration, two rows 104-1, 104-2 and two columns 106-1, 106-2 are shown where four UV-erasable bitcells 150(1,1) to 150(2,2) are particularly depicted. As part of the array 102, bitcells 150(1,1) and 150(1,2) are disposed along row 104-1 and bitcells 150(2,1) and 150(2,2) are disposed along row 104-2. In similar manner, bitcells 150(1,1) and 150(2,1) are disposed along column 106-1 and bitcells 150(1,2) and 150(2,2) are disposed along column 106-2.

Bitcells 150(i,j) may comprise a variety of memory cell architectures depending on technology and implementation. In some examples, the bitcells 150(i,j) may each comprise a wordline select transistor coupled to an FG-based storage transistor, where the bitcells are coupled to a respective supply voltage rail VDD. Representatively, bitcell 150(1,1) is shown as including a wordline select transistor 154, also referred to a select transistor, coupled between VDD and a storage transistor 152, e.g., a FG storage transistor. To effectuate NVM functionality, the gates of wordline select transistors of a row are commonly coupled to a corresponding wordline and the sources of storage transistors of a column are commonly coupled to a corresponding bitline. Accordingly, the array 102 may include as many wordlines and bitlines as there are rows (e.g., M rows) and columns (e.g., N columns), respectively, in an example configuration. Representatively, bitline (BL₁) 108-1 is depicted as being commonly coupled to the sources of bitcells 150(1,1), 150(2,1), . . . , bitline (BL₂) 108-2 is depicted as being commonly coupled to the sources of bitcells 150(1,2), 150(2,2), . . . , and so on. Further, the gates of bitcells 150(1,1), 150(1,2), . . . are commonly coupled to wordline (WL₁) 109-1, the gates of bitcells 150(2,1), 150(2,2), . . . are commonly coupled to wordline (WL₂) 109-2, and so on.

For purposes herein, a “bitline” and a “wordline” are signal paths of a memory array associated with a column of bitcells and a row of bitcells, respectively, where the bitline and/or the wordline may be coupled to suitable circuitry configured to facilitate accessing one or more bitcells with respect to memory read/program/erase operations. In an example arrangement, bitlines 108-1 to 108-N may be coupled to a sense amplifier (SA) block 112 via a column multiplexer (COLMUX) 110 including local multiplex (LMUX) and global multiplex (GMUX) circuitry, where the SA block 112 and COLMUX 110 may be implemented in various ways depending on NVM architecture and technology. In an example arrangement, COLMUX block 110 may include a plurality of individual COLMUX circuits (not specifically shown in FIG. 1) configured to couple respective bitlines 108-j, j=1 to N, to corresponding individual SA blocks 112-1 to 112-K of the SA block 112 for outputting data onto associated data lines 113-1 to 113-K, where K=N/δ, δ being an integer multiplex factor greater than or equal to 1. Further, each individual SA block 112-1 to 112-K may include a sensing interface circuit as part of a data sense path comprising the COLMUX circuit associated with a bitline and a corresponding a sense amplifier. As will be set forth in detail further below, the sensing interface circuit of an individual SA block 112-j, j=1 to K, may include a resistance dependent on supply voltage for modulating the behavior of a sense path transistor according to the examples herein.

An address decoder block 114 is operable for decoding row and column addresses (not specifically shown in FIG. 1) with respect to one or more memory cells selected during read/program/erase operations. Decoded row address (X_DEC) signals 119 and decoded column address (Y_DEC) signals 123 may be provided to WL driver logic block 117 and COLMUX 110, respectively, for selectively activating corresponding wordlines and bitlines with respect to selected memory operations. A control logic block 116 may be provided in association with SA block 112 and address decoder block 114 for facilitating and controlling various memory operations (e.g., read operations, program operations, or erase operations) with respect to selected bitcell(s). For example, the control logic block 116 may be operable responsive to control signals, e.g., read control signal, program control signal, etc. (not specifically shown in FIG. 1) for configuring individual SA blocks including respective sensing interface circuits with respect to a memory operation, buffering/latching of output data, etc. by driving suitable signals 121 including, e.g., timing, reset, etc.

Although the NVM device 100 is shown as including a single bitcell array 102, some examples may involve different memory array layouts including multiple arrays, sectors, pages, etc., as well as variety of cell architectures and/or additional circuitry depending on implementation. For example, bitcell array 102 may be configured as multiple sectors, each sector having corresponding local column multiplex/select circuitry, row drive circuitry, etc., where a global SA block may be multiplexed to bitlines from different sectors via a global multiplex block. In some arrangements, one or more pre-decoder blocks, separate row and column decoders, charge pump circuitry, etc. may also be included in an example NVM device.

In the example of FIG. 1, each bitcell 150(i,j) may include a PMOS storage transistor (e.g., transistor 152) with its source/drain path connected in series with that of a PMOS WL select transistor (e.g., transistor 154) coupled to a power supply voltage rail (e.g., the VDD supply voltage rail) and the corresponding bitline, e.g., bitline 108-1. The gates of select transistors 154 of bitcells in a row are operable to be driven by a common WL control signal asserted on a wordline associated with the row. Because the select transistor 154 is a PMOS device, the corresponding wordline may be energized when WL control signal is driven to a low logic level (e.g., active low) by a corresponding WL driver circuit (not specifically shown in FIG. 1) of the WL driver logic block 117. In some versions of this example, a WL driver circuit may be configured to energize the selected wordline WLᵢ in response to the row address signals 119 that have been at least partially decoded by a pre-decoder (not shown in FIG. 1).

The data state of a given bitcell 150(i,j) depends on whether the storage transistor 152 is programmed to have charge trapped on or in its FG electrode. In this example, unprogrammed or erased state of a bitcell 150(i,j) is the state in which the constituent FG storage transistor 152 is not conductive. Conversely, programmed state of a bitcell 150(i,j) is that in which sufficient charge carriers are trapped at the floating gate electrode to render that transistor 152 conductive upon application of sufficient source-drain voltage. Accordingly, the state of FG storage transistor 152 of bitcell 150(i,j) determines the voltage developed at the associated bitline BLⱼ when the selected wordline WLᵢ is energized so as to turn on the select transistor 154. If bitcell 150(i,j) is programmed, conduction through the storage transistor 152 will apply a suitable voltage level to the bitline BLⱼ when the select transistor 154 is turned on by the energized wordline WLᵢ.

As depicted in FIG. 1, bitlines BLⱼ are coupled to COLMUX block 110, which may be configured to select a particular BLⱼ in response to the decoded column address signals 123 for propagation of a bitline signal to a corresponding SA block 112-j. A sense amplifier of the SA block 112-j may be configured to compare a read current (I_{READ}) signal developed based on the voltage at the selected bitline BLⱼ with a reference current (I_{REF}) level and present a corresponding data state accordingly on a data output path 113-j. Depending on NVM technology and sensing architecture implementation, the read current and the reference current may be compared at different ratios. For example, if I_{REF}>λ*I_{READ}, a logic 0 indicative of an erased state of the selected bitcell 150(i,j) may be output, where λ is a process and/or technology dependent factor. Conversely, if I_{REF}≤λ*I_{READ}, a logic 1 indicative of a programmed state of the selected bitcell 150(i,j) may be output in some example arrangements.

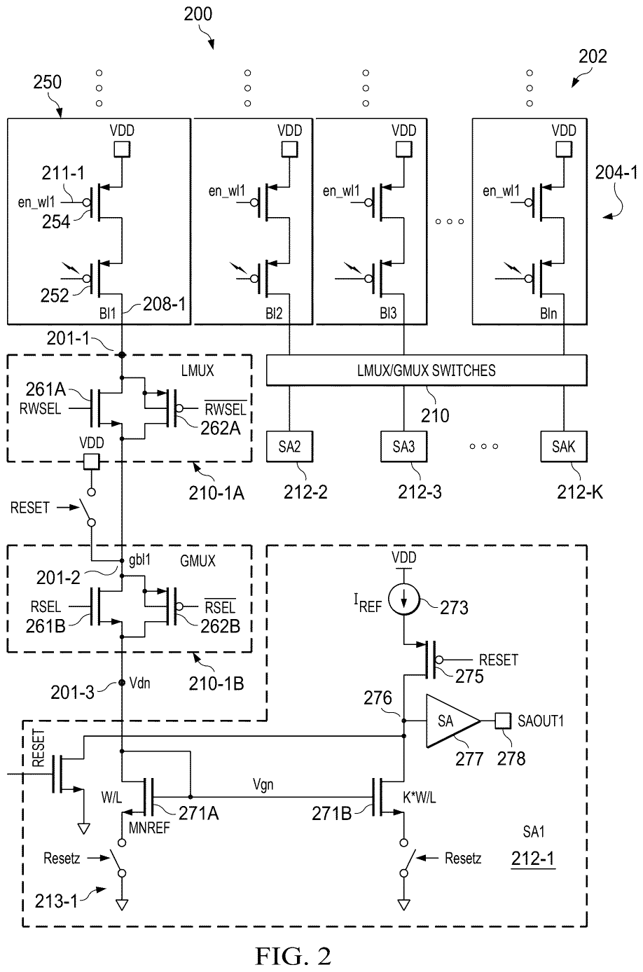

FIG. 2 depicts an example NVM device 200 including additional details of an SA block and associated data sense path circuitry according to a baseline implementation where peripheral circuitry such as address decoder, WL driver logic circuitry, control logic circuitry, etc., are omitted for the sake of clarity. Similar to the arrangement shown in FIG. 1, the NVM device 200 includes a bitcell array 202 comprising N columns and M rows, where row 204-1 is representative of a row of bitcells 250 that are coupled to respective bitlines Bl₁ to BL_{N}. Further, an example bitcell 250 comprises a PMOS select transistor 254 and a PMOS storage transistor 252, similar to the bitcells 150(i,j) described above, where the gates of PMOS select transistors 254 of a row of bitcells 250 are commonly controlled by an enable signal, e.g., en_wl1 211-1. Accordingly, the description of the bitcells 150(i,j) set forth previously is also applicable here with respect to the bitcell architecture shown in the arrangement of FIG. 2.

A column mux/select block 210 including a plurality of LMUX/GMUX circuits is disposed between the bitlines Bl₁ to BL_{N} and respective SA blocks 212-1 to 212-K, where each SA block may include a sensing interface circuit coupled to a sense amplifier. For purposes of the present disclosure, a data sense path may be defined as a path including and formed from devices, circuits, components, etc. disposed between a bitline and the corresponding sense amplifier, where the data sense path may be configured to propagate an electrical signal from the bitline to the sense amplifier for sensing. By way of illustration, transmission gates 210-1A and 210-1B may be provided as LMUX and GMUX circuits, respectively, that are disposed in series and coupled to Bl₁ 208-1. In the example arrangement, LMUX transmission gate 210-1A is formed from an NMOS transistor 261A and a PMOS transistor 262A that are controlled by respective gate signals RWSEL and R̅W̅S̅E̅L̅ that have complementary logic levels. In similar fashion, GMUX transmission gate 210-1B is formed from an NMOS transistor 261B and a PMOS transistor 262B that are controlled by respective gate signals RSEL and R̅S̅E̅L̅ having complementary logic levels.

As illustrated, the transmission gates 210-1A and 210-1B are configured to propagate a read current developed on BL₁ to a sense path transistor 271A, sometimes referred to as MNREF, that is coupled to a ratioed mirror transistor 271B as part of a sensing interface circuit 213-1 of SA1 block 212-1. Transistors 271A and 271B may be provided as NMOS devices having a size W/L and K*W/L, respectively, where transistor 271B may be sized relative to the size of transistor 271A so as to mirror the read current by a multiple K, that is, with a 1:K ratio. Transistor 271B may be configured to provide the ratioed current a sense input node 276 coupled to the sense amplifier 277. The ratio factor K may be selected based on the NVM technology and application. In some examples, transistor 271A may have a W/L ratio of 1 μm/3 μm and the mirror transistor 271B may have a size multiple K=2, although different sizes and/or multiples may be provided in other arrangements.

A reference current source 273 operable with a supply voltage (VDD) may be configured to provide a reference current (I_{REF}) to the sense input node 276 during a read cycle by selectively activating a PMOS switch 275 under control of a Reset signal. In operation, a comparison of I_{REF} and the ratioed read current (K*I_{READ}) at the sense input node 276 is operable to develop a voltage at the sense input node 276, which is sensed by the sense amplifier 277 for generating a corresponding data at an output data node 278. In some arrangements, the sense amplifier 277 may be operable as an inverter such that the data at node 278 has a logic value complementary to the logic value developed at the sense input node 276 in response to the current comparison. For example, if I_{REF}>K*I_{READ}, the sense input node 276 is pulled to VDD, thus resulting in a data output of 0 indicative of an erased state of a selected bitcell coupled to BL₁.

To coordinate read cycle operations, various switches and gates may be provided in association with the NVM device 200, where the switches and gates may be operable under control of appropriate control and timing signals depending on implementation. In an example arrangement, appropriate reset signals may be derived from or based on one or more signals from a control logic block (e.g., control logic block 116 shown in FIG. 1), including one or more internal and/or external clock signals. By way of illustration, one or more Reset and Resetz signals may be provided in addition to RWSEL/R̅W̅S̅E̅L̅ and RSEL/R̅S̅E̅L̅ signals to selectively activate appropriate gates and switches for effectuating a read/sensing operation.

In an example arrangement, the NVM device 200 may be disposed in a

“reset” phase prior to a read cycle, where the sensing interface circuitry is configured such that the output data nodes 278 are set to a logic high or “1” as default. In this reset phase, the bitlines are connected to VDD through respective gates, e.g., PMOS switches having gate signals at 0 V during the reset phase. Moreover, the sense input nodes 276 of respective sense amplifiers are grounded, e.g., pulled to 0 V, which ensures that the SA output is set to logic “1”, e.g., VDD.

In the example shown in FIG. 2, one or more Reset signals may be provided as having a first voltage level (e.g., VDD) during the reset phase and a second voltage level (e.g., 0 V) during the read phase. On the other hand, one or more Resetz signals may be provided as having complementary levels with respect to Reset signals, e.g., Resetz signals having 0 V during the reset phase and VDD during the read phase. Further, the voltages at R̅W̅S̅E̅L̅ and RSEL signals may be set to VDD during the reset phase and 0 V during the read phase.

Responsive to suitable address, control and clock signals generated or otherwise provided for commencing a read phase, appropriate voltages are applied at RWSEL and RSEL signals for turning on the LMUX/GMUX transmission gates associated with selected bitline(s) based on decoded address signals. In some examples, voltages having twice the VDD levels may be applied in order to reduce the switch resistance of selected LMUX/GMUX transmission gate(s).

Focusing on the scenario of reading a single bitcell as an example, current developed on the bitline during a read cycle is sensed by the sense path transistor (e.g., MNREF 271A) to generate a gate voltage Vgn. As set forth previously, the current at the selected bitline, which may be referred to as read current (I_{READ}), bitcell current, bitline current, memory current, etc., is dependent on the logic state of the storage transistor of the bitcell. Because the gate and the drain of MNREF 271A are shorted in this example, the voltage Vgn of MNREF 271A is the same as the voltage at Vdn node 201-3 coupled to the drain of MNREF 271A. The current sensed by MNREF 271A is mirrored by the ratioed mirror transistor 271B, which provides a ratioed IREAD to the sense input node 276 for comparison and data output by the sense amplifier 277 as previously set forth.

Because the transmission gates 210-1A and 210-1B along a data sense path may be configured to operate as switches having minimal resistance, various nodes along the data sense path prior to an SA block, e.g., SA block 212-1, may have roughly similar voltage levels. For example, a BL node 201-1, a global bitline (gbl) node 201-2 and the Vdn node 201-3 coupled to the drain of MNREF 271A are roughly at the same voltage level. Further, the source-drain voltage (Vds) across a storage transistor is roughly equal to the difference between VDD and Vdn. As the drain and gate of MNREF 271A disposed along the data sense path are shorted, the Vdn and Vgn track each other. Moreover, the Vgn of MNREF 271A is correlated to the threshold (Vth) of MNREF 271A because Vgn is the same as the gate-to-source (Vgs) of MNREF 271A. As a result, variations in the Vth of MNREF 217A due to process corner variations may cause corresponding variations in the voltage levels at Vgn and Vdn nodes. Because the relationship VDD−Vdn≈Vds holds and because Vdn=Vgn of MNREF 271A, variations in Vdn can cause unacceptable deviations in the Vds of the storage transistor, leading to misreading of a stored 1 (in weak process corners, e.g., resulting in increased Vth) and/or rendering the bitcell susceptible to soft programming (in strong process corners, e.g., resulting in lower Vth) as previously noted.

Whereas the drain and gate nodes of a sense path transistor, e.g., MNREF 271A, of the example of FIG. 2 are shorted, thus giving rise to the foregoing deleterious effects, examples according to the present disclosure include sensing interface circuitry where the drain and gate nodes of a sense path transistor are not shorted, thus facilitating a voltage separation between the drain and gates depending on the supply voltage levels as will be set forth below. As the drain is decoupled from the gate, the voltage level of the drain, thus the voltage level at a Vdn node along the data sense path, may be independently controlled to obtain a more precise Vds across the bitcell storage element in order to meet appropriate power budget specifications. Further, because the drain and gate nodes of the sense path transistors are not shorted, the effects of process corner variations that result in Vth variations of the sense path transistors are not propagated to the bitcells. Accordingly, a more robust sensing interface may be realized in an example NVM implementation of the present disclosure.

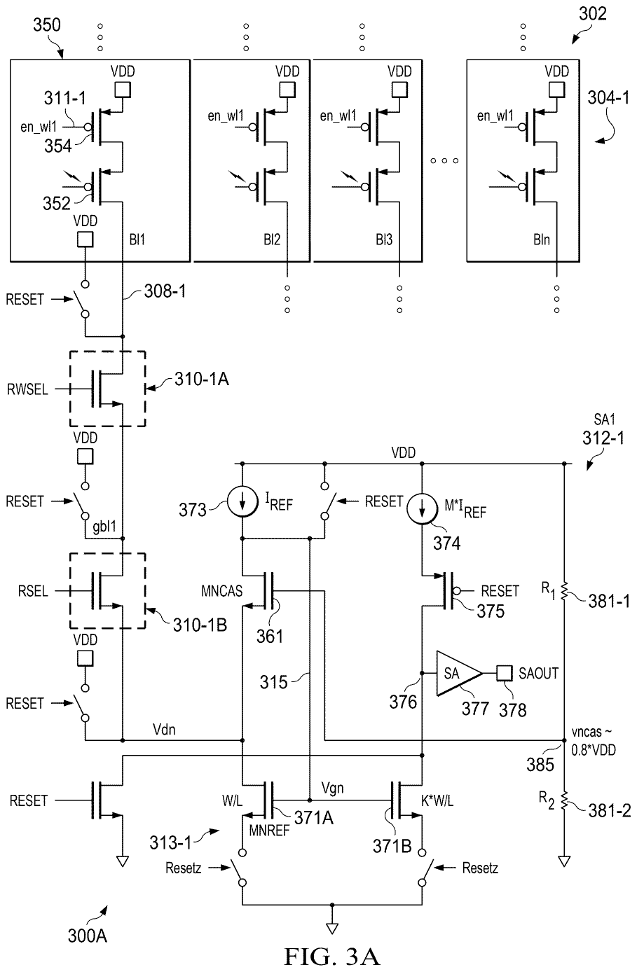

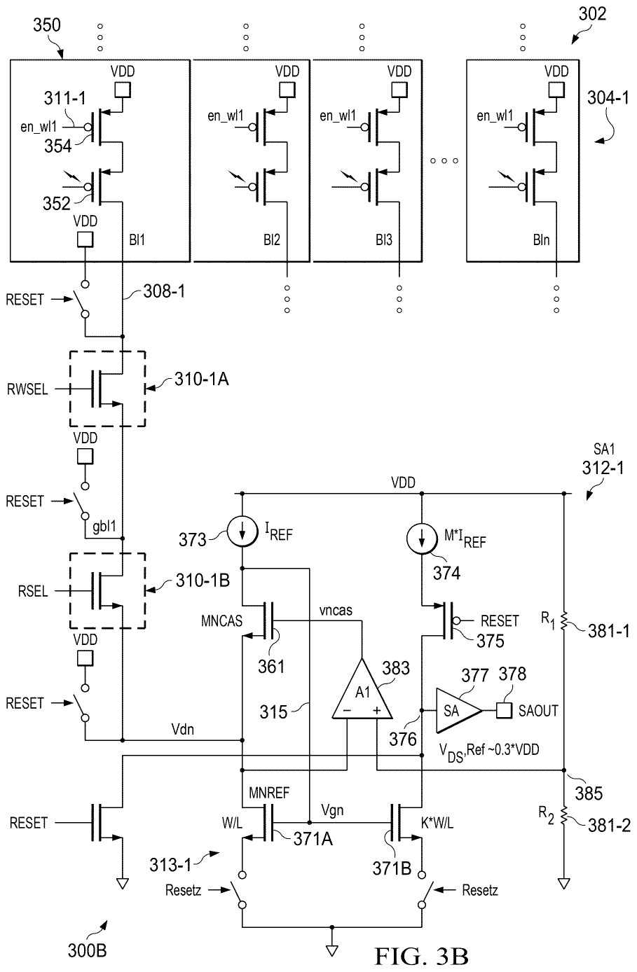

FIGS. 3A and 3B depict block diagrams of a semiconductor device, e.g., an NVM device, including sensing interface circuitry according to some examples of the present disclosure. As will be set forth below, the examples herein provide a feedback mechanism as part of NVM sensing interface circuitry where a resistance dependent on supply voltage is configured to modulate the behavior of a sense path transistor such that the risks of misreading of programmed data at weak process corners of a low supply voltage application as well as soft programming at strong process corners of a high supply voltage application are advantageously mitigated. Accordingly, the NVM arrangements herein may be configured to operate as standalone devices, IPs, macros, etc. having broader versatility with respect to a range of supply voltage environments.

As illustrated, NVM device 300A of FIG. 3A and NVM device 300B of FIG. 3B are analogous to each other, which include two variations of a feedback mechanism, respectively, for controlling sense path transistors according to some examples. Further, NVM devices 300A and 300B may have a memory architecture analogous to the architecture of NVM device 100 shown in FIG. 1. In addition, similar to the arrangement shown in FIG. 2, NVM devices 300A 300B are illustrated without peripheral circuitry such as address decoder, WL driver logic circuitry, control logic circuitry, etc. for the sake of clarity. Accordingly, FIGS. 3A and 3B are described together in the following sections where the details of an SA block and associated data sense path circuitry including a resistance dependent on supply voltage as part of a feedback mechanism according to some examples herein.

Similar to the arrangement shown in FIG. 1, NVM devices 300A and 300B include a bitcell array 302 comprising N columns and M rows, where row 304-1 is representative of a row of bitcells 350 that are coupled to respective bitlines Bl₁ to BL_{N}. Further, an example bitcell 350 comprises a PMOS select transistor 354 and a PMOS storage transistor 352, similar to the bitcells 150(i,j) described above, where the gates of PMOS select transistors 354 of a row of bitcells 350 are commonly controlled by an enable signal, e.g., en_wl1 311-1. Accordingly, the description of the bitcells 150(i,j) set forth previously is also applicable here with respect to the bitcell architecture shown in the arrangements of FIGS. 3A and 3B.

A column mux/select block (not specifically shown in FIGS. 3A and 3B) including a plurality of LMUX/GMUX circuits is disposed between the bitlines Bl₁ to BL_{N} and associated SA blocks, e.g., SAₖ, k=1 to K, where each SA block may include a sensing interface circuit coupled to a sense amplifier. By way of example, SA1 block 312-1 including a sensing interface circuit 313-1 coupled to the sense amplifier 377 is shown with respect to BL₁ 308-1 in FIGS. 3A and 3B, where SA blocks and LMUX/GMUX circuitry associated with remaining bitlines are omitted for the sake of clarity. As previously set forth, a data sense path may be defined for purposes of the present disclosure as a path disposed between a bitline, e.g., BL1 308-1, and the corresponding sense amplifier, e.g., SA 377, configured to propagate an electrical signal to the sense amplifier for sensing. Further, a data sense path according to examples herein may include one or more transistors, gates, or other devices that may be utilized in the propagation of bitcell current/voltage signals for sensing, where such devices may be controlled or otherwise modulated by a resistance dependent on the supply voltage utilizing a feedback mechanism as set forth in further detail below. Accordingly, the example sensing interface circuitry may be implemented in a variety of known or heretofore unknown memory technologies, e.g., including but not limited to, EPROM, EEPROM, Flash, OTP/MTP, and the like.

As illustrated in FIGS. 3A and 3B, the sensing interface circuit 313-1 includes a sense path transistor (MNREF) 371A coupled to a ratioed mirror transistor 371B for providing a multiple of input current to a sense input node 376 of the sense amplifier 377. In an example arrangement, transistors 371A and 371B may be provided as NMOS devices having a size W/L and K*W/L, respectively, where transistor 371B may be sized relative to the size of transistor 371A so as to mirror the input current by a multiple K, that is, with a 1:K ratio, similar to the arrangement shown in FIG. 2. Likewise, different transistor sizes and ratio factors (K) may be provided in an example sensing interface arrangement depending on implementation and NVM application. For example, transistor 371A may have a W/L ratio of 1 μm/3 μm and transistor 371B may have a size multiple K=2 similar to the arrangement shown in FIG. 2, although other sizes and/or multiples may be provided in some additional and/or alternative arrangements.

Whereas the sensing interface circuitry 213-1 in FIG. 2 is configured to facilitate data sensing based on a comparison between a ratioed I_{READ} current and non-ratioed I_{REF} current, examples herein provide a sensing scheme that includes a ratioed I_{REF} current. Accordingly, the sensing interface circuit 313-1 also includes circuitry configured to provide a ratioed I_{REF} at the sense input node 376 of the sense amplifier 377. In an example arrangement, a ratioed reference current source 374 is powered by VDD, where a ratioed reference current output M*I_{REF} is gated by a PMOS switch 375 under control of a Reset signal similar to the PMOS switch 275 of the example shown in FIG. 2.

Further, a reference current source 373 powered by VDD is operable to provide an IREF current for facilitating proper operation and biasing of a MOS device 361, sometimes referred to as MNCAS, which may be configured to operate as a voltage-dependent resistance provided as part of a feedback loop for modulating the voltage level at the drain of the sense path transistor 371A. In addition, the output of the reference current source 373 is coupled to the gates of the sense path transistor 371A and the ratioed mirror transistor 371B. Accordingly, during a reading operation, the ratioed mirror transistor 371B is operable to conduct a current K*(I_{REF}+I_{READ}), which is compared against the ratioed I_{REF} current (e.g., M*I_{REF}) at the sense input node 376. Equivalently, a current of (M−K)*I_{REF} is compared against K*I_{READ} for outputting a corresponding data level by the sense amplifier 377. For example, if (M−K)*I_{REF} is >K*I_{READ}, a logic 0 (indicating an erased bit) may be output at node 378. Conversely, if K*I_{READ} is ≥(M−K)*I_{REF}, a logic 1 (indicating a programmed bit) may be output at node 378. In an example scenario, if M=3 and K=2, the sensing operation reduces to a comparison between I_{REF} and 2*I_{READ}, which analogous to the sensing operation set forth in the example of FIG. 2. For purposes of the present disclosure, a current provided by the ratioed mirror transistor 371B to the sense input node 376 may be referred to as a sense current, where the sense current may be a function of at least a ratioed bitcell current, a ratioed reference current and/or in any combination thereof, based on implementation and NVM application.

In the examples shown in FIGS. 3A and 3B, the reference current source 373 and the ratioed reference current source 374 may be implemented as PMOS devices having the same gate voltage generated by a suitable bias generator (not shown in FIG. 3A/3B). Depending on implementation, the PMOS devices may be suitably sized or scaled to obtain desired reference current ratios. Further, the ratio factors, e.g., M and K, used in the examples herein may be selected based on NVM technology, application environment, etc.

In the examples herein, an NMOS device may be provided as MNCAS 361 where the gate of MNCAS 361 may be controlled by a supply-dependent feedback signal such that MNCAS 361 is operable to provide different resistances depending on the supply voltage levels. In an example arrangement, gate bias for MNCAS 361 may be provided as being proportional to VDD. At higher VDD levels, Vgs of MNCAS 361 increases, and therefore the resistance offered by MNCAS 361 decreases. Accordingly, for higher VDD levels, MNCAS 361 is operable essentially as a short. Conversely, MNCAS 361 provides a higher resistance for lower VDD levels, thus leading to a voltage drop across the MNCAS device.

In the scenario of higher VDD, therefore, the voltage levels of Vdn and Vgn associated with the sense path transistor 371A are the same because of a connection path 315 that is shorted through MNCAS 361. Because there is a risk of soft programming of bitcells at strong process corners (as the Vth becomes lower at strong process corners, it leads to lower Vgn, which in turn lowers Vdn, thus causing a higher Vds across the bitcell storage transistor), especially at higher VDD supplies, the sense path transistor 371A may be sized so as to maintain a sufficiently high Vdn level and thus limit the Vds to a specified value.

On the other hand, sizing the sense path transistor 371A to increase Vgn can reduce the gate-source (Vgs) “headroom” of LMUX/GMUX devices in low VDD applications where the Vdn and Vgn nodes along a data sense path are shorted. A low Vgs of the LMUX/GMUX devices may therefore cause a higher resistance at the devices, thus leading to a reduced bitcell current. Consequently, the risk of false reading of programmed bits may increase particularly in low VDD applications as previously noted.

The risk of false reading of programmed bits in low VDD scenarios is advantageously mitigated in the examples herein, however, because the drain and gate nodes of the sense path transistor 371A are at different voltage levels due to the voltage drop caused by MNCAS 361. In particular, the voltage level at the drain (e.g., Vdn) is less than the voltage at the gate (e.g., Vgn). Accordingly, the Vgs of LMUX/GMUX devices is not negatively impacted, which improves the conduction of the devices. In some examples, the Vdn voltage level may be reduced to sufficient levels (by operating/biasing MNCAS at a suitable level to provide appropriate resistance (R), resulting in a corresponding iR drop) in low VDD conditions. In some examples, the conduction of LMUX/GMUX devices is sufficiently improved such that LMUX/GMUX circuity may be implemented using only NMOS devices instead of using both NMOS and PMOS devices in a transmission gate arrangement as shown in the example of FIG. 2. As illustrated in FIGS. 3A and 3B, LMUX 310-1A and GMUX 310-1B may therefore comprise NMOS devices controlled by suitable control signals RWSEL and RSEL to control and coordinate a sensing operation according to the examples herein. The LMUX 310-1A and GMUX 310-1B may individually or collectively be referred to as a column multiplex element. Further, similar to the example of FIG. 2, one or more clock and control signals (e.g., one or more Reset and Resetz signals) controlling suitable reset switches, devices, etc., may be provided along a data sense path for synchronizing the sensing operations of the examples set forth in FIGS. 3A and 3B. Because PMOS devices are omitted in the formation of LMUX/GMUX circuitry according to the examples herein, bitline capacitance associated with the data sense path may be reduced, which may decrease propagation delays and thus improve access times in some arrangements. Furthermore, the die size area including the NVM examples of FIGS. 3A and 3B may be reduced because of the omission of PMOS devices in the LMUX/GMUX circuitry thereof.

In some examples, a voltage divider circuit including a series of resistors disposed between VDD and a ground node may be provided for generating a suitable bias signal to control MNCAS 361 as part of a dynamic supply-dependent feedback mechanism. In some arrangements, a fractional VDD (e.g., α*VDD, 0<α≤1) may be generated at an output node 385 of a voltage divider comprising resistors R1 381-1 and R2 381-2. In some arrangements, the values of R1 381-1, R2 381-2 and α may be selected based on power budget, process technology, NVM application environment, etc. For example, R1 and R2 may comprise resistors having resistance values on the order of several kΩ in some implementations.

In some examples, the fractional VDD output at node 385 may be directly coupled to the gate of MNCAS 361 as shown in the arrangement of FIG. 3A, where α is illustratively provided as having a value of 0.8. In this arrangement, MNCAS 361 is operable as a short (for higher VDD levels) or as a high resistance voltage drop (for lower VDD levels) without having a reference to the voltage conditions at a Vdn node. Accordingly, for lower VDD scenarios, the voltage drop caused by MNCAS 361 may be configured to create a sufficient voltage difference between Vdn and Vgn that is advantageous in mitigating the risk of false reading of programmed bits while maintaining a coarse control over the Vds of the bitcells.

In some examples, the fractional voltage output at node 385 may be set to a particular value which may be provided as a non-inverting input (e.g., a first input) to an amplifier (A1) 383 having an inverting input (e.g., a second input) coupled to the Vdn node, as shown in FIG. 3B. In this arrangement, the negative feedback loop comprising MNCAS 361, amplifier 383 and MNREF 371A is operable to ensure that the voltage level at Vdn is equal to the output voltage of the voltage divider, which allows for more robust control (e.g., more granular control) over the Vds of the bitcells across the process corner variations. In an example arrangement, the output voltage at the node 385 may be set at β*VDD, where β is around 0.3.

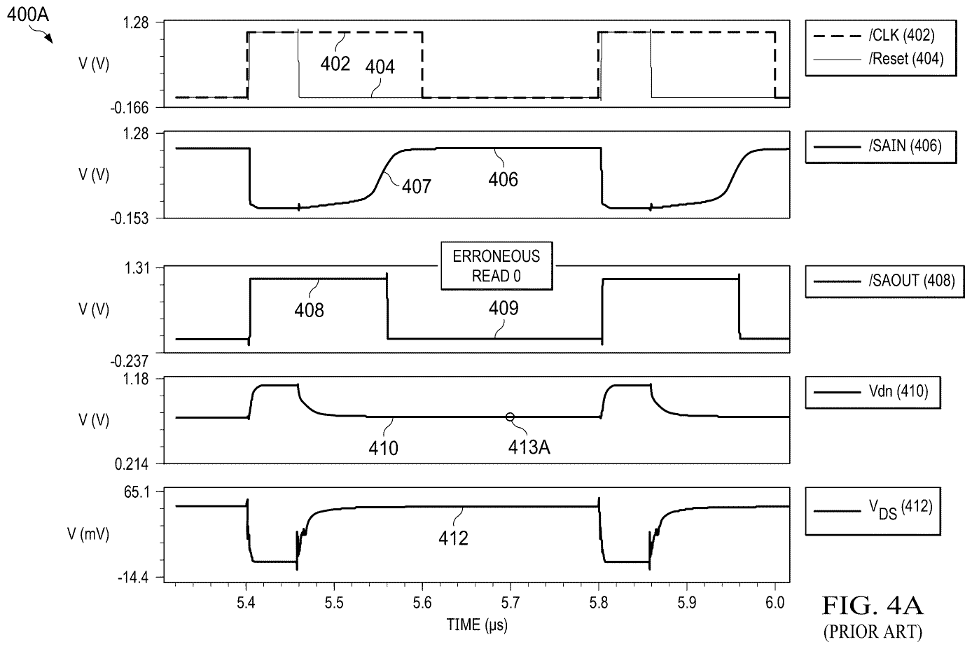

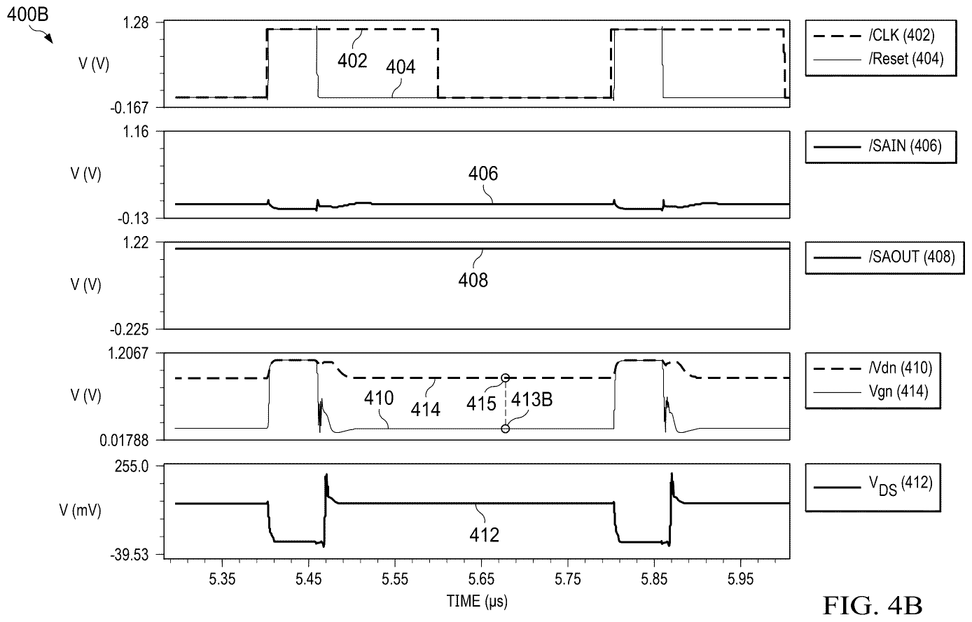

FIG. 4A depicts a waveform panel 400A associated with a baseline sensing architecture illustrating a false read scenario in an example low VDD application. FIG. 4B depicts a waveform panel 400B associated with a sensing architecture of the present disclosure illustrating absence of a false read scenario in an example low VDD application. As depicted, waveform panels 400A and 400B include timing diagrams of various signals activated or otherwise involved in a read operation for an NVM device operating at a VDD of 1.1 V and in a weak process corner (e.g., at temperatures around −55° C.). In the baseline sensing architecture, Vdn and Vgn nodes are shorted, leading to a high resistance of the LMUX/GMUX switches at low VDD levels as previously described. On the other hand, Vdn and Vgn nodes are isolated in an example sensing architecture of the present disclosure, allowing the Vdn node to have a lower voltage level as set forth above with respect to the arrangements of FIGS. 3A and 3B.

Waveform panels 400A and 400B each include a clock (CLK) 402 that may be provided by a control logic block and a Reset signal 404 that may be generated in response to CLK 402 by respective sensing architectures of a baseline arrangement and an example of the present disclosure. As CLK 402 is asserted for initiating a read cycle with respect to a selected bitcell based on appropriate address and enable signals (not specifically shown in FIGS. 4A and 4B), Reset signal 404 transitions from a default logic high level to a logic low level. In response, a sense input (SAIN) signal 406 transitions to a logic low in order that the corresponding sense amplifier may output a logic high for indicating a programmed state of the bitcell. However, in the baseline sensing architecture, SAIN 406 rises to a logic high as indicated by a rising edge 407 shown in FIG. 4A, which causes the sense amplifier to transition from a default logic high state to a logic low 409 as illustrated by a falling edge 411 in a data output (SAOUT) signal 408 instead of outputting (or continuing to output) a logic high corresponding to the programmed state of the bitcell. Depending on the slew rate of the falling edge 411, the logic low 409 may be latched at a suitable time to be output as a data bit 0. Further, waveforms 410, 412 associated with voltage levels at Vdn (which is the same as Vgn in the baseline sensing architecture) and across the source-drain of the bitcell's storage transistor (e.g., Vds), respectively, are shown in FIG. 4A. As illustrated by reference number 413A, Vdn waveform 410 displays a voltage of approximately 730 mV during the read phase.

In contrast, SAIN 406 in the example sensing architecture of the present disclosure remains at a logic low, thus causing SAOUT 408 to continue to output a logic high during the read phase. As there is no spurious transition to a logic low, SAOUT 408 correctly outputs the programmed state of the bitcell, as shown in the waveform panel 400B of FIG. 4B. Because Vdn and Vgn nodes are decoupled in the example sensing architecture of the present disclosure, separate waveforms 410, 414 associated with voltage levels of Vdn and Vgn, respectively, are shown FIG. 4B. As illustrated by reference number 413B, Vdn waveform 410 displays a voltage of approximately 176 mV during the read phase according to the example sensing architecture of the present disclosure. Further, Vgn waveform 414 displays a voltage of approximately 853 mV during the read phase as illustrated by reference number 415 according to the example sensing architecture of the present disclosure. As compared with the waveform panel 400A of FIG. 4A, the Vdn level associated with the example sensing architecture is sufficiently low (e.g., 176 mV<<730 mV) so as not to inhibit the conduction of the LMUX/GMUX switches and thus reduce the bitcell current.

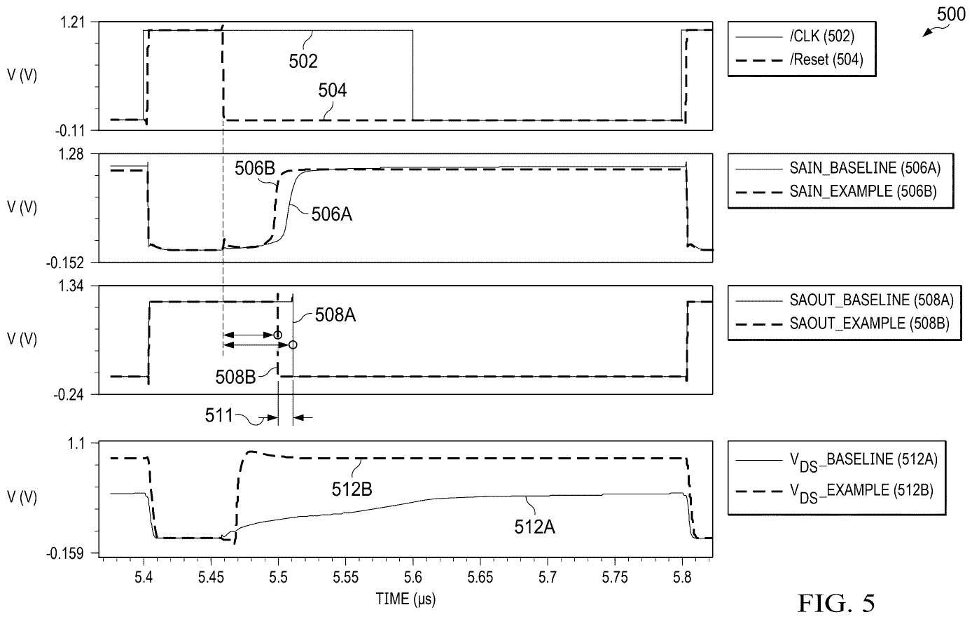

FIG. 5 depicts waveforms associated with a baseline sensing architecture and a sensing architecture of the present disclosure illustrating reduced read access time according to some examples. Analogous to the waveform panels 400A/400B above, a waveform panel 500 of FIG. 5 displays CLK 502 and Reset 504 for commencing a read phase in a low VDD application scenario, e.g., VDD=1.1 V, involving a weak process corner (e.g., at temperatures around −55° C.). SAIN signals 506A, 506B correspond to sense input signals in a baseline sensing architecture and an example sensing architecture of the present disclosure, respectively. SAOUT signals 508A, 508B correspond to data output signals responsive to SAIN signals 506A, 506B, respectively, where a timing difference 511 between the baseline SAOUT 508A and the example SAOUT 508B is seen in transitioning from the default logic state to the logic low (indicating the erased state of the bitcell being read). Because of the earlier transitioning in SAOUT signal 508B, data can be latched earlier, leading to a faster data output. In some examples, the difference in read access times between a baseline sensing architecture and an example sensing architecture of the present disclosure may be in the order of several nanoseconds.

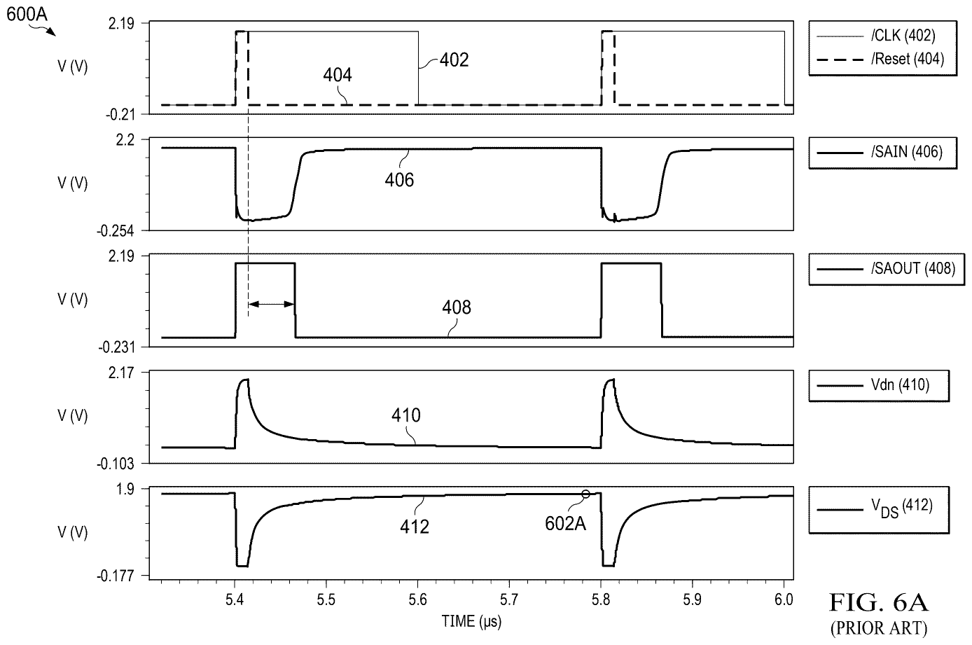

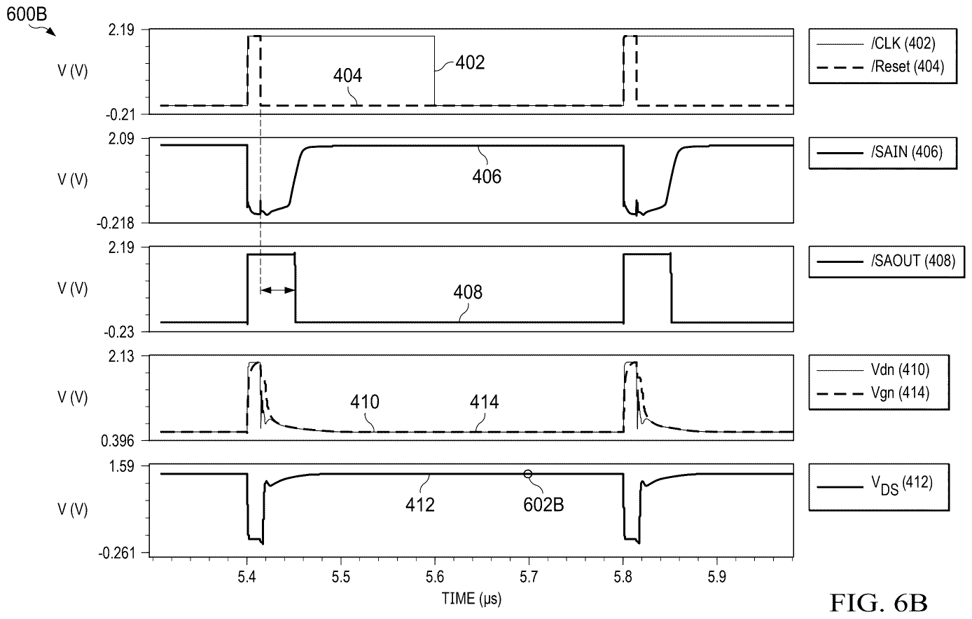

FIGS. 6A and 6B depict waveforms associated with a baseline sensing architecture and a sensing architecture of the present disclosure, respectively, which illustrate reduced voltage stress (e.g., Vds) across a storage element according to some examples. By way of illustration, signal waveforms are displayed for a strong process corner at temperatures around 150° C. and VDD=1.98 V for an NVM device including a baseline sensing architecture and an example of the present disclosure in waveform panels 600A and 600B, respectively. Analogous to the waveform panels 400A, 400B shown in FIGS. 4A and 4B, the waveform panels 600A and 600B depict CLK 402 and Reset 404 for commencing an access cycle. As shown in the waveform panel 600A, a voltage level 602A of about 1.72 V is developed in the Vds waveform 412 during the access cycle associated with the baseline sensing architecture. In contrast, a voltage level 602B of about 1.42 V is seen in the Vds waveform 412 of FIG. 6B associated with the example sensing architecture. Where a Vds limit of 1.5 V is specified for a technology node, having a Vds of 1.72 V across the bitcell storage transistors is not desirable because such voltage deviations may increase the risk of soft programming as previously noted.

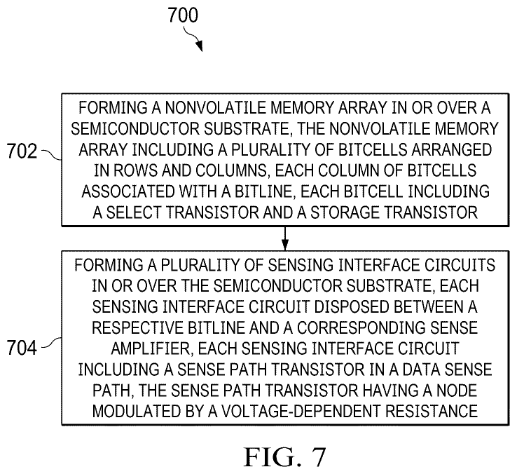

FIG. 7 is a flowchart of a method of fabricating a semiconductor device (e.g., NVM devices 300A or 300B) including a nonvolatile memory core or array according to some examples of the present disclosure. Method 700 may commence with forming a nonvolatile memory array in or over a semiconductor substrate, where the nonvolatile memory array may include a plurality of bitcells arranged in rows and columns, as set forth at block 702. In some examples, the semiconductor substrate may comprise a wafer of suitable semiconductor material, e.g., Si, Ge, GaAs, SiC, other Group III-V materials, polysilicon, doped Si, etc., where the bitcells may be fabricated using a variety of technologies and process nodes, e.g., including Linear BiCMOS or LBC, without limitation. Each column of bitcells may be associated with a bitline, where each bitcell includes a select transistor and a storage transistor. At block 704, a plurality of sensing interface circuits may be formed in or over the semiconductor substrate, each sensing interface circuit disposed between a respective bitline and a corresponding sense amplifier. In an example arrangement, a sensing interface circuit may be fabricated to include a sense path transistor (e.g., an NMOS device) disposed on a data sense path and a supply voltage dependent resistance operable to modulate a node (e.g., drain) of the sense path transistor. As set forth above, providing a supply voltage dependent resistance to modulate the drain allows the drain to have a voltage level lower than a gate voltage level. In this manner, source-drain voltage across the bitcells'storage transistors may be controlled in a robust fashion over a range of supply voltages.

Although examples including a PMOS-based UV-EPROM architecture have been set forth in particular detail above, the teachings herein are not necessarily limited thereto. Some examples may therefore include NVM architectures based on NMOS and/or CMOS technologies where a sensing architecture including supply-dependent resistance may be provided as previously noted.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a nonvolatile memory array including a plurality of bitcells arranged in rows and columns, each column of bitcells associated with a corresponding bitline, each bitcell including a select transistor and a storage transistor; and
a plurality of sensing interface circuits, each sensing interface circuit disposed between a respective bitline and a corresponding sense amplifier, each sensing interface circuit including a sense path transistor having a node configurable to have a voltage modulated by a voltage-dependent resistance.

2. The semiconductor device of claim 1, wherein the voltage-dependent resistance comprises an n-channel MOS (NMOS) transistor having a gate driven by a voltage divider coupled to a supply voltage rail.

3. The semiconductor device of claim 1, wherein the voltage-dependent resistance comprises an NMOS transistor having a gate connected to an output of an operational amplifier having a first input coupled to a voltage divider coupled to a supply voltage rail and a second input coupled to the node of the sense path transistor.

4. The semiconductor device of claim 3, wherein the first input is a non-inverting input and the second input is an inverting input.

5. The semiconductor device of claim 3, wherein the voltage divider comprises a series of resistors selected to provide a scaled supply voltage corresponding to a source-drain voltage across the storage transistor of a bitcell.

6. The semiconductor device of claim 1, wherein the sense path transistor is coupled to a ratioed mirror transistor configurable to provide a sense current that is a function of a ratioed bitcell current and a ratioed reference current to the sense amplifier corresponding to a bitline.

7. The semiconductor device of claim 1, wherein each bitline is coupled to two NMOS transistors disposed in series, the NMOS transistors configured as a column multiplex element coupled to a respective one of the plurality of sensing interface circuits.

8. The semiconductor device of claim 1, wherein the sense path transistor is an NMOS transistor having a device size configurable to limit a source-drain voltage across the storage transistor of a bitcell to a particular value.

9. A method of fabricating a semiconductor device, comprising:
forming a nonvolatile memory array in or over a semiconductor substrate, the nonvolatile memory array including a plurality of bitcells arranged in rows and columns, each column of bitcells associated with a corresponding bitline, each bitcell including a select transistor and a storage transistor; and
forming a plurality of sensing interface circuits in or over the semiconductor substrate, each sensing interface circuit disposed between a respective corresponding bitline and a corresponding sense amplifier, each sensing interface circuit including a sense path transistor having a node configurable to have a voltage modulated by a voltage-dependent resistance.

10. The method of claim 9, further comprising forming a column multiplex element comprising two n-channel MOS (NMOS) transistors coupled in series, the column multiplex element disposed between a bitline and a respective one of the plurality of sensing interface circuits.

11. The method of claim 9, wherein the voltage-dependent resistance is formed as an n-channel MOS (NMOS) transistor having a gate driven by a voltage divider coupled to a supply voltage rail.

12. The method of claim 9, wherein the voltage-dependent resistance is formed as an NMOS transistor having a gate driven by an operational amplifier having a first input coupled to a voltage divider coupled to a supply voltage rail and a second input coupled to the node of the sense path transistor.

13. The method of claim 12, wherein the first input is formed as a non-inverting input and the second input is formed as an inverting input.

14. The method of claim 12, wherein the voltage divider is formed using resistors selected to provide a scaled supply voltage corresponding to a source-drain voltage across the storage transistor of a bitcell.

15. The method of claim 9, further comprising forming a ratioed mirror transistor coupled to the sense path transistor, the ratioed mirror transistor configured to provide a sense current that is a function of a ratioed bitcell current and a ratioed reference current to the sense amplifier corresponding to a bitline.

16. The method of claim 9, wherein the sense path transistor is formed as an NMOS transistor having a device size configured to limit a source-drain voltage across the storage transistor of a bitcell to a particular value.
